(19) United States
(12) Patent Application Publication
(10) Pub. No.: US 2025/0379166 A1
(43) Pub. Date: Dec. 11, 2025

(54) REPAIR STRUCTURE FOR BONDED SEMICONDUCTOR DEVICE

(71) Applicant: International Business Machines Corporation, Armonk, NY (US)

(72) Inventors: Nicholas Alexander Polomoff, Hopewell Junction, NY (US); Ashim Dutta, Clifton Park, NY (US); Chih-Chao Yang, Glenmont, NY (US); Kishan Jayanand, Cohoes, NY (US); Nicholas Latham, Albany, NY (US); Sathyanarayanan Raghavan, Ballston Lake, NY (US)

(21) Appl. No.: 18/739,666

(22) Filed: Jun. 11, 2024

(51) Int. Cl. H01L 23/00

(52) U.S. Cl. CPC H01L 24/05; H01L 24/08; H01L 2224/0519; H01L 2224/0569; H01L 2224/08145; H01L 2924/0665; H01L 2924/3512

(57) ABSTRACT

A semiconductor device comprises a first semiconductor structure bonded to a second semiconductor structure, a plurality of metal pads at an interface portion between the first semiconductor structure and the second semiconductor structure, and a structure disposed around the plurality of metal pads, wherein the structure comprises a plurality of chemical agents.

### BACKGROUND

Innovations in semiconductor fabrication and packaging technologies have enabled the development of smaller scale, higher density semiconductor integrated circuit (IC) chips, as well as the development of highly integrated chip modules with wiring and area array input/output (I/O) contact densities that enable dense packaging of IC chips. For certain applications, high-performance electronic devices are constructed by fabricating semiconductor devices on separate wafers and bonding the wafers together to construct an integrated semiconductor device package.

### SUMMARY

Embodiments of the disclosure include a repair structure for bonded semiconductor devices.

In one embodiment, a semiconductor device includes a first semiconductor structure bonded to a second semiconductor structure, a plurality of metal pads at an interface portion between the first semiconductor structure and the second semiconductor structure, and a structure disposed around the plurality of metal pads, wherein the structure comprises a plurality of chemical agents.

In another embodiment, a semiconductor device includes a first semiconductor structure comprising a first plurality of metal pads, and a second semiconductor structure comprising a second plurality of metal pads. The first semiconductor structure is bonded to the second semiconductor structure, and respective ones of the first plurality of metal pads are aligned with respective ones of the second plurality of metal pads. A repair structure is disposed around the respective ones of the first plurality of metal pads and the second plurality of metal pads.

In another embodiment, a semiconductor device includes two or more semiconductor dies hybrid bonded together, a plurality of metal structures at an interface portion between a first semiconductor die of the two or more semiconductor dies and a second semiconductor die of the two or more semiconductor dies, and a structure disposed around respective ones of the plurality of metal structures, wherein the structure comprises a plurality of chemical agents.

These and other features and advantages of embodiments described herein will become more apparent from the accompanying drawings and the following detailed description.

### BRIEF DESCRIPTION OF THE DRAWINGS

FIGS. 1 and 2 depict cross-sectional views of first and second semiconductor structures each including hybrid bonding level dielectric layers and metal levels, according to an embodiment of the invention.

FIGS. 3 and 4 depict cross-sectional views of the first and second semiconductor structures following photoresist patterning and removal of portions of the hybrid bonding level dielectric layers to form openings for repair structures, according to an embodiment of the invention.

FIGS. 5 and 6 depict cross-sectional views of the first and second semiconductor structures following deposition of the repair structures, according to an embodiment of the invention.

FIG. 7 depicts a cross-sectional view of the first and second semiconductor

structures following flipping of the first semiconductor structure onto the second semiconductor structure, and bonding of the first semiconductor structure with the second semiconductor structure to create a first bonded semiconductor structure, according to an embodiment of the invention.

FIG. 8 depicts a cross-sectional view of a second bonded semiconductor structure with alternative repair structures, according to an embodiment of the invention.

FIGS. 9, 10 and 11 depict three-dimensional views of the second bonded semiconductor structure with alternative repair structures, according to an embodiment of the invention.

FIG. 12 depicts a cross-sectional view of a third bonded semiconductor structure with alternative repair structures, according to an embodiment of the invention.

FIGS. 13 and 14 depict three-dimensional views of the third bonded semiconductor structure with alternative repair structures, according to an embodiment of the invention.

FIG. 15 depicts a cross-sectional view illustrating crack development in the first bonded semiconductor structure, according to an embodiment of the invention.

FIG. 16 depicts a cross-sectional view illustrating polymerization of a plurality of healing agents and filling in of cracks in the first bonded semiconductor structure, according to an embodiment of the invention.

FIG. 17 depicts a cross-sectional view of a fourth bonded semiconductor structure with alternative repair structures, according to an embodiment of the invention.

### DETAILED DESCRIPTION

Embodiments of the disclosure will now be discussed in further detail with regard to structures for and techniques for forming a repair structure for bonded semiconductor devices to prevent crack propagation. It is to be understood that the various layers, structures, and regions shown in the accompanying drawings are schematic illustrations that are not drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. The term “exemplary” as used herein means “serving as an example, instance, or illustration.” Any embodiment or design described herein as “exemplary” is not to be construed as preferred or advantageous over other embodiments or designs. The word “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

Further, the term “semiconductor die” or “die” as used herein refers to a block of semiconductor material on which a given functional circuit (e.g., memory circuit, processor circuitry, etc.) and metallization levels (e.g., front-end-of-line (FEOL), middle-of-line (MOL), back-end-of-line (BEOL) metallization levels) are fabricated. Similarly, a semiconductor structure may also refer to a block of semiconductor material on which a given functional circuit and metallization levels are fabricated.

As used herein, “high-K” refers to dielectric materials having a relative dielectric constant greater than 7.

As used herein, “low-K” refers to dielectric materials having a relative dielectric constant less than 7, and includes ultra-low-k dielectric materials.

As used herein, “hybrid bonding” refers to a 3D packing technique to connect semiconductor structures. Hybrid bonding forms connections of semiconductor structures through metal pads which are embedded in a dielectric layer at a bond interface on each semiconductor structure that is being bonded. Fusion bonding forms connections of semiconductor structures via dielectric layers at a bond interface on each semiconductor structure being bonded.

Various conventional techniques, such as two-dimensional (2-D) packaging and three-dimensional (3-D) packaging techniques, can be utilized to construct a semiconductor device package structure. With 2-D packaging, package structures can be constructed by connecting multiple semiconductor IC dies directly to a package substrate using direct chip attachment (DCA) techniques (e.g., flip-chip bonding), wherein the semiconductor IC chips are mounted in the package laterally adjacent to each other (e.g., in a single plane, or coplanar to each other). In this regard, 2-D packaging techniques can require a relatively large package footprint to accommodate multiple semiconductor IC chips. In addition, the I/O communication paths between adjacent chips can be very long since chip-to-chip I/O communication is made through chip-substrate-chip connections and interfaces, which can result in noisy and long interconnect lengths, which can degrade signal integrity.

On the other hand, with 3-D packaging, two more semiconductor IC chips are vertically stacked on top of each other, and interconnected (without an intermediate layer or package substrate) using vertical interconnection structures such as through silicon via (TSV) interconnect structures. While 3-D packaging can provide improvement in communication bandwidth between the stacked chips, there are various problematic issues associated with 3-D packaging.

For example, some issues associated with current 3-D packaging approaches include, but are not limited to: (i) reliability issues of bonded structures; (ii) increased noise from power supplies at high frequency due to high speed circuit switching; (iii) decreased stack assembly yield, requiring more chip real estate for yield loss mitigation through, for example, redundancy; (iv) requirements for extra chip processing such as backside thinning to keep the stacked chips as thin as possible as well as extra fabrication specific steps for TSVs; (v) chip stacking limits, etc.

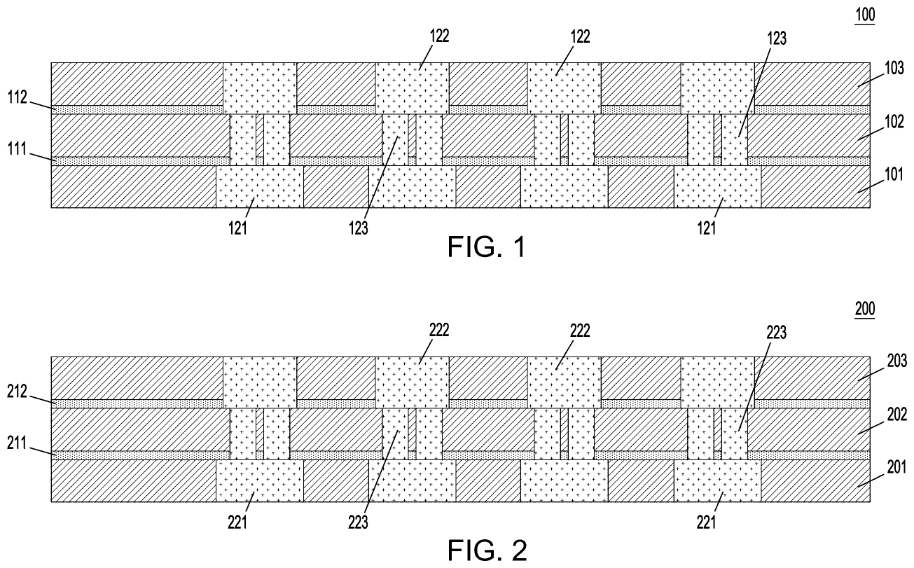

Referring to FIGS. 1 and 2, a first semiconductor structure 100 and a second semiconductor structure 200 (or “first semiconductor die” and “second semiconductor die”) respectively include a plurality of first outer contacts 121 and a plurality of second outer contacts 221 in a first metallization level (e.g., FEOL, MOL and/or BEOL metallization level), and a plurality of first interface contacts 122 and a plurality of second interface contacts 222 in a second metallization level. A plurality of first vias 123 connect the first outer contacts 121 and the first interface contacts 122, and a plurality of second vias 223 connect the second outer contacts 221 and the second interface contacts 222. In illustrative embodiments, multiple first vias 123 connect respective ones of the first outer contacts 121 to respective ones of the first interface contacts 122, and multiple second vias 223 connect respective ones of the second outer contacts 221 to respective ones of the second interface contacts 222.

The first outer contacts 121, the first interface contacts 122 and the first vias 123 are formed in a first dielectric layer stack including dielectric layers 101, 102 and 103 alternately stacked with dielectric layers 111 and 112. The second outer contacts 221, the second interface contacts 222 and the second vias 223 are formed in a second dielectric layer stack including dielectric layers 201, 202 and 203 alternately stacked with dielectric layers 211 and 212. The dielectric layers 101/201, 102/202 and 103/203 include, but are not necessarily limited to, tetraethyl orthosilicate (TEOS), silicon dioxide (SiO2), carbon-doped silicon oxide (SiCOH), SiLK® dielectrics, and/or porous forms of these dielectric films. The dielectric layers 111/211 and 112/212 include, but are not necessarily limited to, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) or other nitride material. In a non-limiting illustrative embodiment, dielectric layers 101/201, 102/202 and 103/203 include the same materials as each other, and the dielectric layers 111/211 and 112/212 include the same materials as each other.

As can be understood by one of ordinary skill in the art, the first and second dielectric layer stacks can be on the first and second semiconductor substrates (not shown), with intervening layers (e.g., lower conductive lines, devices, etc.) between the first and second dielectric layer stacks and the first and second semiconductor substrates. A plurality of devices can be on or within the first and second semiconductor substrates, such as, for example, transistors, capacitors, and resistors.

The first outer contacts 121, the first interface contacts 122, the second outer contacts 221 and the second interface contacts 222 can be for example, pads or other interconnects. In illustrative embodiments, the first outer contacts 121, the first interface contacts 122, the second outer contacts 221, the second interface contacts 222, the first vias 123 and the second vias 223, include, for example, a silicide layer, such as a silicide formed with Ni, Ti, NiPt, etc., a metal adhesion layer, such as TiN, TiW, Ta/TaN, etc., and a conductive metal fill layer, such as Cu, W, Al, Co, Ru, etc., and can be deposited using, for example, a deposition technique such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), sputtering and/or plating, followed by a planarization process such as, chemical mechanical planarization (CMP) to remove excess portions of the metal material from on top of dielectric layers.

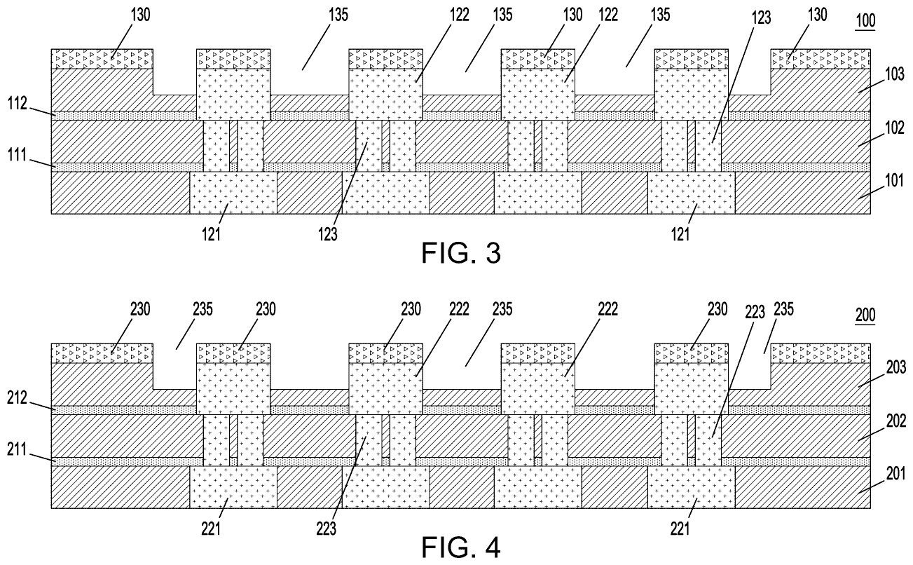

Referring to FIGS. 3 and 4, a first photoresist 130 and a second photoresist 230 are respectively deposited on the first interface contacts 122 and the second interface contacts 222. The first photoresist 130 is also deposited on the dielectric layer 103, and the second photoresist 230 is also deposited on the dielectric layer 203. The first and second photoresists 130 and 230 are patterned to expose portions of the dielectric layers 103 and 203 that are etched to create first and second recessed portions 135 and 235 in the dielectric layer 103 and the dielectric layer 203, respectively. The etch can be performed using a reactive ion etching (RIE) process.

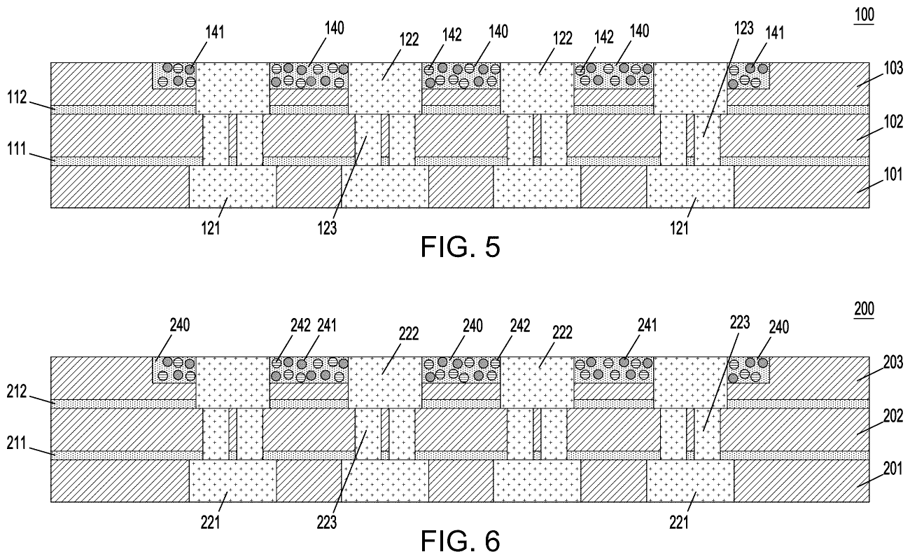

Referring to FIGS. 5 and 6, following etching of the exposed portions of the dielectric layers 103 and 203, the first and second photoresists 130 and 230 are removed. A first repair structure 140 is deposited in the first recessed portions 135 around the first interface contacts 122, and a second repair structure 240 is deposited in the second recessed portions 235 around the second interface contacts 222. The first repair structure 140 comprises a plurality of first healing agents 141 and a plurality of first catalysts 142 in an organic (e.g., resin) matrix. The second repair structure 240 comprises a plurality of second healing agents 241 and a plurality of second catalysts 242 in a resin matrix. In illustrative embodiments, the plurality of first healing agents 141 and the plurality of second healing agents 241 comprise dicyclopentadiene (DCPD), 5-ethylidene-2-norbornene (ENB), DCPD/ENB blends, a mixture of hydroxyl end functionalized polydimethylsiloxane (HOPMDS) and polydiethoxysiloxane (PDES), epoxy or a styrene-based system. In the case of DCPD, ENB and DCPD/ENB blends, the plurality of first and second catalysts 142 and 242 comprise a Grubbs catalyst (Bis(tricyclohexylphosphene) benzylidine ruthenium (IV) dichloride). Grubbs catalysts are a series of transition metal carbene complexes used as catalysts. Other non-limiting illustrative examples of Grubbs catalysts include unsaturated N-heterocyclic carbene (1,3-bis(2,4,6-trimethylphenyl) imidazole)) and saturated N-heterocyclic carbene (1,3-bis(2,4,6-trimethylphenyl) dihydroimidazole).

In the case of a mixture of hydroxyl end functionalized polydimethylsiloxane (HOPMDS) and polydiethoxysiloxane (PDES), the plurality of first and second catalysts 142 and 242 comprise Di-n-butyltin dilaurate. In the case of epoxy, the plurality of first and second catalysts 142 and 242 comprise amine, and in the case of a styrene-based system, the plurality of first and second catalysts 142 and 242 comprise cobalt naphthenate or dimethylaniline. Additional polydimethylsiloxane (PDMS) polymers contain different amounts of polyaniline (PANI).

In illustrative embodiments, the plurality of first healing agents 141, the plurality of second healing agents 241, the plurality of first catalysts 142 and the plurality of second catalysts 242 are in capsules (e.g., microcapsules). For example, the first and second repair structures 140 and 240 may be deposited as a dielectric (e.g., epoxy resin) matrix slurry including the microcapsules, and then cured/heat treated. The conditions for curing or heat treatment may comprise, for example, curing or thermosetting at temperature ranges of about 50° C. to about 200°° C. for durations of from about 3 minutes to about 5 hours. Some self-healing materials require exposure to UV light or other forms of radiation to initiate and complete their respective curing processes. Conditions are dependent on the material selection, composition and the geometries of the fabricated structure (e.g., thickness of the structure embedded into the joining interface of the dielectric). As explained in more detail herein, the first and second catalysts 142 and 242 are structured to polymerize the first and second healing agents 141 and 241 upon contacting the first and second healing agents 141 and 241. Illustratively, the plurality of first healing agents 141 and the plurality of second healing agents 241 can comprise capsules of thermoset polymer or a glass sphere filled with one of the healing agent materials noted hereinabove in an organic matrix. In some cases, the first and second repair structures 140 and 240 may be painted-on coatings.

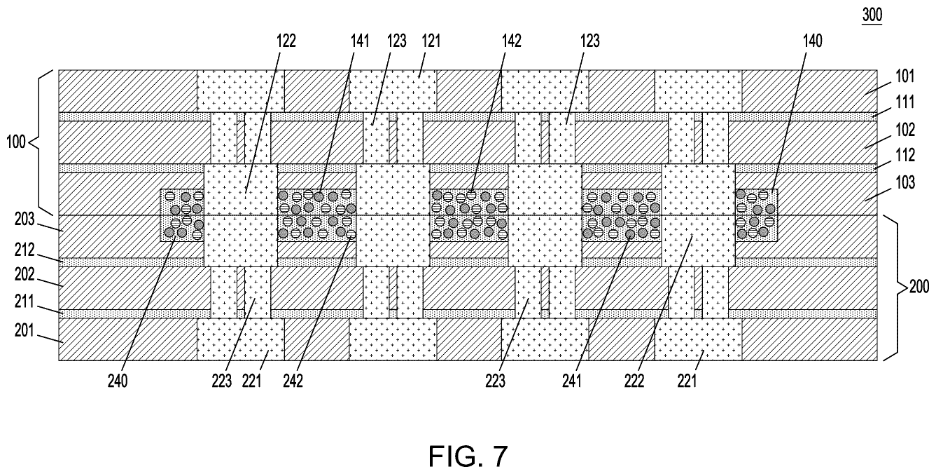

Following deposition and curing of the first and second repair structures 140 and 240, the first and second semiconductor structures 100 and 200 are planarized using, for example, chemical mechanical planarization (CMP). Then, referring to FIG. 7, in a first bonded semiconductor structure 300, the first semiconductor structure 100 is flipped (e.g., rotated 180 degrees) onto the second semiconductor structure 200 so that the first semiconductor structure 100 faces the second semiconductor structure 200. As used herein, the terms “face,” “faces” or “facing” refer to the result of rotating one of two structures 180 degrees so that top surfaces of the structures can be positioned opposite and aligned with each other.

In flipping the first semiconductor structure 100 onto the second semiconductor structure 200, first interface contacts 122 of the first semiconductor structure 100 are aligned with the second interface contacts 222 of the second semiconductor structure 200. In addition, the first repair structure 140 of the first semiconductor structure 100 is aligned with second repair structure 240 of the second semiconductor structure 200. In an illustrative embodiment, the first repair structure 140 has the same chemical composition as the second repair structure 240. Respective ones of the first interface contacts 122 are aligned with and disposed opposite to respective ones of second interface contacts 222. In addition, the respective ones of the first interface contacts 122 are disposed in dielectric layer 103 and the respective ones of second interface contacts 222 are disposed in dielectric layer 203. Similarly, respective portions of the first repair structure 140 are aligned with and disposed opposite to respective portions of the second repair structure 240. The respective portions of the first repair structure 140 are disposed in dielectric layer 103 around the first interface contacts 122 and the respective portions of the second repair structure 240 are disposed in dielectric layer 203 around the second interface contacts 222.

A heat treatment process is performed on the semiconductor device to anneal the metal material of the first interface contacts 122 and the second interface contacts 222. The heat treatment completes the hybrid bonding process so that the first semiconductor structure 100 is hybrid bonded to the second semiconductor structure 200. As a result of the annealing, the opposing first and second interface contacts 122 and 222 are formed (e.g., integrated) into respective metal structures (also referred to herein as “metal pads”) that span (e.g., bridge) across an interface between the first and second semiconductor structures 100 and 200. The conditions of the heat treatment process include, for example, heat treating at about 200° C. to about 400° C. for about 1 hour to 3 hours. In an illustrative embodiment, the heat treatment is performed at 300° C. to about 400° C. for about 1 hour to about 2 hours.

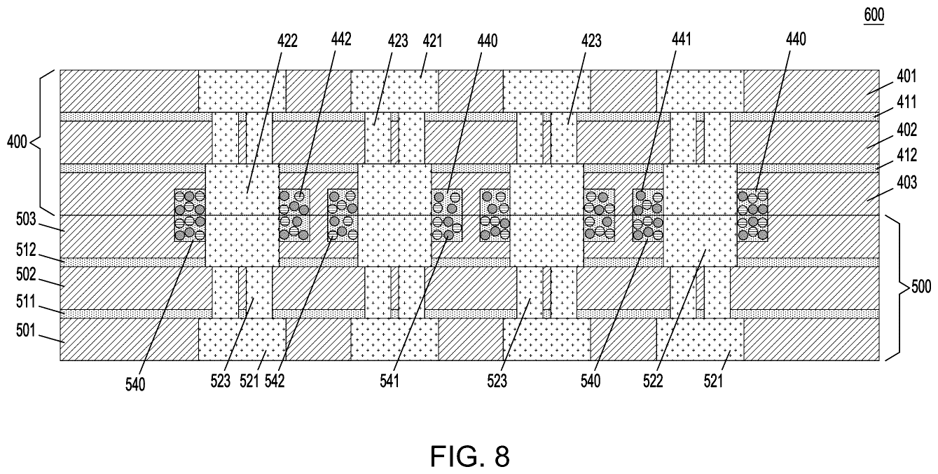

Similar to what is shown in FIG. 7, FIG. 8 depicts a cross-sectional view of a second bonded semiconductor structure 600 with another first semiconductor structure 400 hybrid bonded to another second semiconductor structure 500. In more detail, the other first semiconductor structure 400 has been flipped and is positioned on top of the other second semiconductor structure 500. With similar reference numerals representing the same or similar elements, the other first semiconductor structure 400 and the other second semiconductor structure 500 includes a plurality of first outer contacts 421 and a plurality of second outer contacts 521 in a first metallization level (e.g., FEOL, MOL and/or BEOL metallization level), and a plurality of first interface contacts 422 and a plurality of second interface contacts 522 in a second metallization level. A plurality of first vias 423 connect the first outer contacts 421 and the first interface contacts 422, and a plurality of second vias 523 connect the second outer contacts 521 and the second interface contacts 522. In illustrative embodiments, multiple first vias 423 connect respective ones of the first outer contacts 421 to respective ones of the first interface contacts 422, and multiple second vias 523 connect respective ones of the second outer contacts 521 to respective ones of the second interface contacts 522.

The first outer contacts 421, the first interface contacts 422 and the first vias 423 of the other first semiconductor structure 400 are formed in a first dielectric layer stack including dielectric layers 401, 402 and 403 alternately stacked with dielectric layers 411 and 412. The second outer contacts 521, the second interface contacts 522 and the second vias 523 of the other second semiconductor structure 500 are formed in a second dielectric layer stack including dielectric layers 501, 502 and 503 alternately stacked with dielectric layers 511 and 512. The dielectric layers 401/501, 402/502, 403/503, 411/511 and 412/512 include, but are not necessarily limited to, the same or similar materials as those of the dielectric layers 101/201, 102/202, 103/203, 111/211 and 112/212, respectively.

The first outer contacts 421, the first interface contacts 422, the second outer contacts 521 and the second interface contacts 522 can be for example, pads or other interconnects. In illustrative embodiments, the first outer contacts 421, the first interface contacts 422, the second outer contacts 521, the second interface contacts 522, the first vias 423 and the second vias 523 include the same or similar materials as the first outer contacts 121, the first interface contacts 122, the second outer contacts 221, the second interface contacts 222, the first vias 123 and the second vias 223, respectively, and can be deposited using, for example, deposition techniques such as CVD, PECVD, RFCVD, PVD, ALD, MBD, PLD, LSMCD, sputtering and/or plating, followed by a planarization process such as, CMP to remove excess portions of the metal material from on top of dielectric layers.

First and second repair structures 440 and 540 of the other first semiconductor structure 400 and the other second semiconductor structure 500, respectively, are similar in composition and location to the first and second repair structures 140 and 240 of the first semiconductor structure 100 and the second semiconductor structure 200, respectively. For example, the first repair structure 440 comprises a plurality of first healing agents 441 and a plurality of first catalysts 442 in an organic (e.g., resin) matrix which are the same as or similar to the first healing agents 141 and the first catalysts 142. The second repair structure 540 comprises a plurality of second healing agents 541 and a plurality of second catalysts 542 in a resin matrix which are the same as or similar to the second healing agents 241 and the second catalysts 242.

Similar to the first and second repair structures 140 and 240, in illustrative embodiments, the plurality of first healing agents 441, the plurality of second healing agents 541, the plurality of first catalysts 442 and the plurality of second catalysts 542 are in capsules (e.g., microcapsules). Unlike the first and second repair structures 140 and 240, portions of the first and second repair structures 440 and 540 of the other first semiconductor structure 400 and the other second semiconductor structure 500, which are disposed around respective ones of the metal structures formed by opposing pairs of the first and second interface contacts 422 and 522, are spaced apart from each other. In other words, respective portions of the first and second repair structures 440 and 540 corresponding to respective opposing pairs of the first and second interface contacts 422 and 522 are separated from each other by portions of dielectric layers (e.g., dielectric layers 403 and 503).

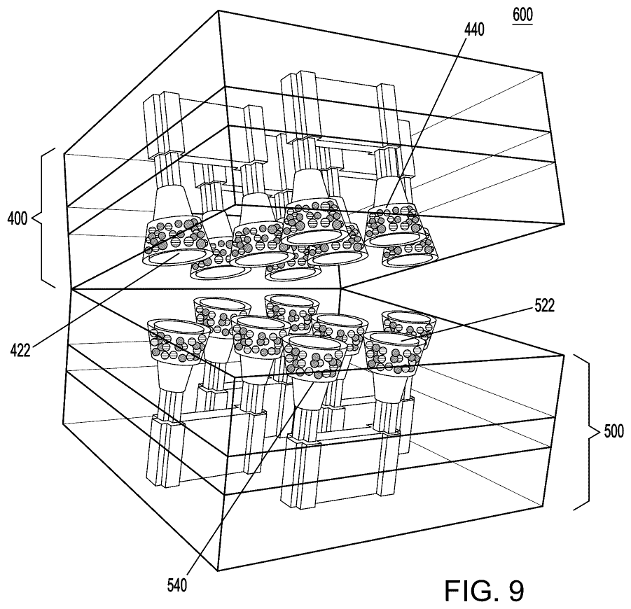

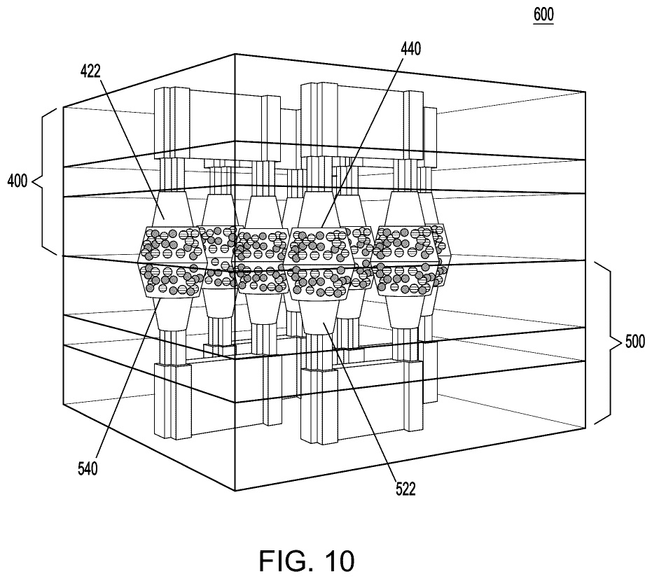

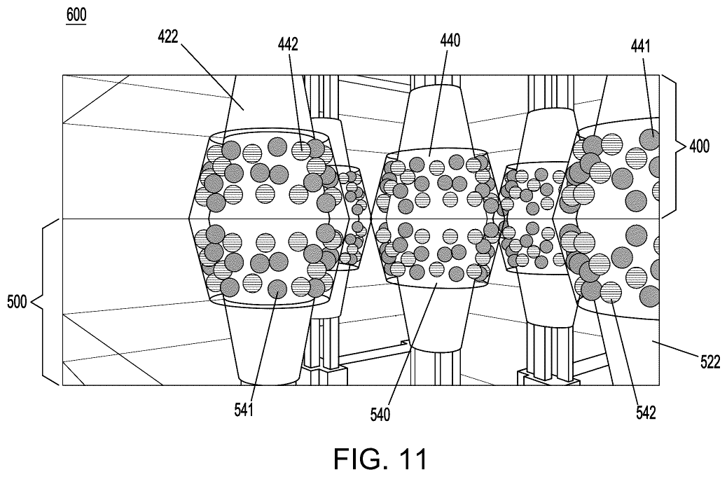

FIGS. 9, 10 and 11 depict three-dimensional views of the second bonded semiconductor structure 600 with the respective portions of the first and second repair structures 440 and 540 disposed around the respective opposing pairs of the first and second interface contacts 422 and 522.

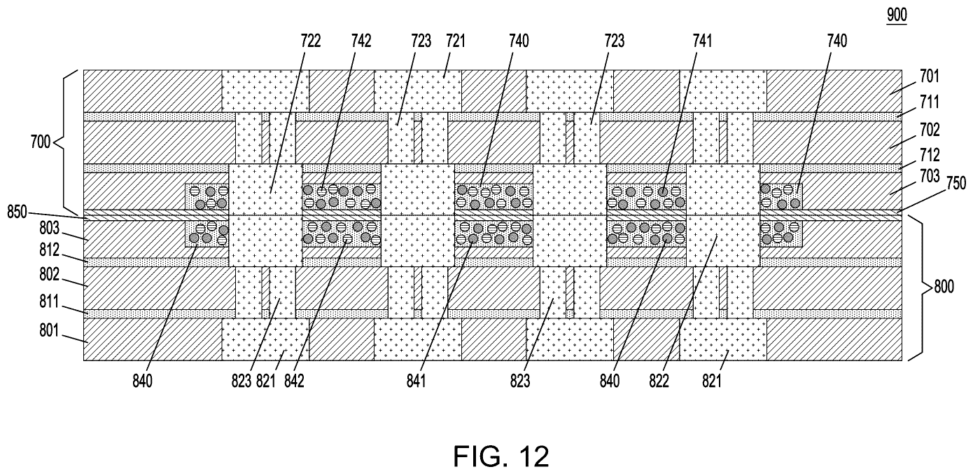

Similar to what is shown in FIG. 7, FIG. 12 depicts a cross-sectional view of a third bonded semiconductor structure 900 with an additional first semiconductor structure 700 hybrid bonded to an additional second semiconductor structure 800. In more detail, the additional first semiconductor structure 700 has been flipped and is positioned on top of the additional second semiconductor structure 800. With similar reference numerals representing the same or similar elements, the additional first semiconductor structure 700 and the additional second semiconductor structure 800 includes a plurality of first outer contacts 721 and a plurality of second outer contacts 821 in a first metallization level (e.g., FEOL, MOL and/or BEOL metallization level), and a plurality of first interface contacts 722 and a plurality of second interface contacts 822 in a second metallization level. A plurality of first vias 723 connect the first outer contacts 721 and the first interface contacts 722, and a plurality of second vias 823 connect the second outer contacts 821 and the second interface contacts 822. In illustrative embodiments, multiple first vias 723 connect respective ones of the first outer contacts 721 to respective ones of the first interface contacts 722, and multiple second vias 823 connect respective ones of the second outer contacts 821 to respective ones of the second interface contacts 822.

The first outer contacts 721, the first interface contacts 722 and the first vias 723 of the additional first semiconductor structure 700 are formed in a first dielectric layer stack including dielectric layers 701, 702 and 703 alternately stacked with dielectric layers 711 and 712, and a first interface dielectric layer 750 formed on the dielectric layer 703. The second outer contacts 821, the second interface contacts 822 and the second vias 823 of the additional second semiconductor structure 800 are formed in a second dielectric layer stack including dielectric layers 801, 802 and 803 alternately stacked with dielectric layers 811 and 812, and a second interface dielectric layer 850 formed on the dielectric layer 803. The dielectric layers 701/801, 702/802, 703/803, 711/811 and 712/812 include, but are not necessarily limited to, the same or similar materials as those of the dielectric layers 101/201, 102/202, 103/203, 111/211 and 112/212, respectively. In an illustrative embodiment, the first and second interface dielectric layers 750 and 850 comprise a nitride such as, for example, SiN, SiON, SiCN, BN, SiBN, SiBCN, SiOCN or other nitride material.

The first outer contacts 721, the first interface contacts 722, the second outer contacts 821 and the second interface contacts 822 can be for example, pads or other interconnects. In illustrative embodiments, the first outer contacts 721, the first interface contacts 722, the second outer contacts 821, the second interface contacts 822, the first vias 723 and the second vias 823 include the same or similar materials as the first outer contacts 121, the first interface contacts 122, the second outer contacts 221, the second interface contacts 222, the first vias 123 and the second vias 223, respectively, and can be deposited using, for example, deposition techniques such as CVD, PECVD, RFCVD, PVD, ALD, MBD, PLD, LSMCD, sputtering and/or plating, followed by a planarization process such as, CMP to remove excess portions of the metal material from on top of dielectric layers.

First and second repair structures 740 and 840 of the additional first semiconductor structure 700 and the additional second semiconductor structure 800, respectively, are similar in composition and location to the first and second repair structures 140 and 240 of the first semiconductor structure 100 and the second semiconductor structure 200, respectively. For example, the first repair structure 740 comprises a plurality of first healing agents 741 and a plurality of first catalysts 742 in an organic (e.g., resin) matrix which are the same as or similar to the first healing agents 141 and the first catalysts 142. The second repair structure 840 comprises a plurality of second healing agents 841 and a plurality of second catalysts 842 in a resin matrix which are the same as or similar to the second healing agents 241 and the second catalysts 242.

Similar to the first and second repair structures 140 and 240, in illustrative embodiments, the plurality of first healing agents 741, the plurality of second healing agents 841, the plurality of first catalysts 742 and the plurality of second catalysts 842 are in capsules (e.g., microcapsules). Unlike the first and second repair structures 140 and 240, the first and second repair structures 740 and 840 are separated from each other by the first and second interface dielectric layers 750 and 850 disposed between the first and second repair structures 740 and 840. In other words, the first and second interface dielectric layers 750 and 850 are formed on the opposing surfaces of the first and second repair structures 740 and 840 that face each other when the additional first semiconductor structure 700 is bonded with the additional second semiconductor structure 800. Accordingly, the opposing surfaces of the first and second repair structures 740 and 840 are recessed with respect to the opposing surfaces of the respective pairs of the first and second interface contacts 722 and 822 and are isolated from each other by the first and second interface dielectric layers 750 and 850.

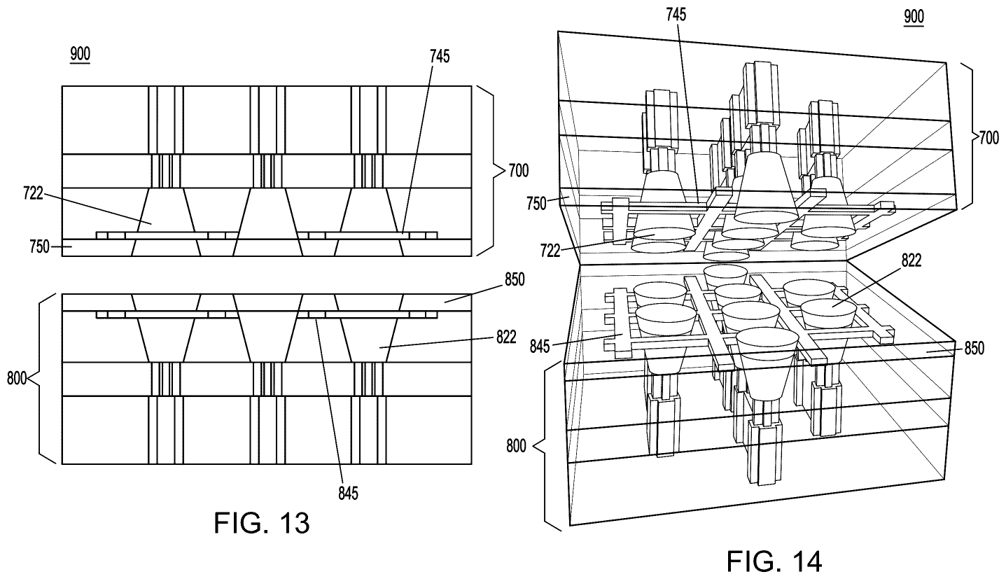

In illustrative embodiments, as can be seen in the three-dimensional views of the third bonded semiconductor structure 900 in FIGS. 13 and 14, the first repair structures 740 are disposed in first channels 745 and the second repair structures 840 are disposed in second channels 845. In illustrative embodiments, the first and second channels 745 and 845 are microchannels embedded (e.g., buried) in the first and second interface dielectric layers 750 and 850. The first and second channels 745 and 845 are disposed around the metal structures formed by opposing pairs of the first and second interface contacts 722 and 822. The chemical composition of the first and second repair structures 740 and 840 may be different from or the same as each other.

In FIGS. 13 and 14, the three-dimensional views of the third bonded semiconductor structure 900 depict the first and second channels 745 and 845 embedded in the first and second interface dielectric layers 750 and 850 and disposed around the respective opposing pairs of the first and second interface contacts 722 and 822.

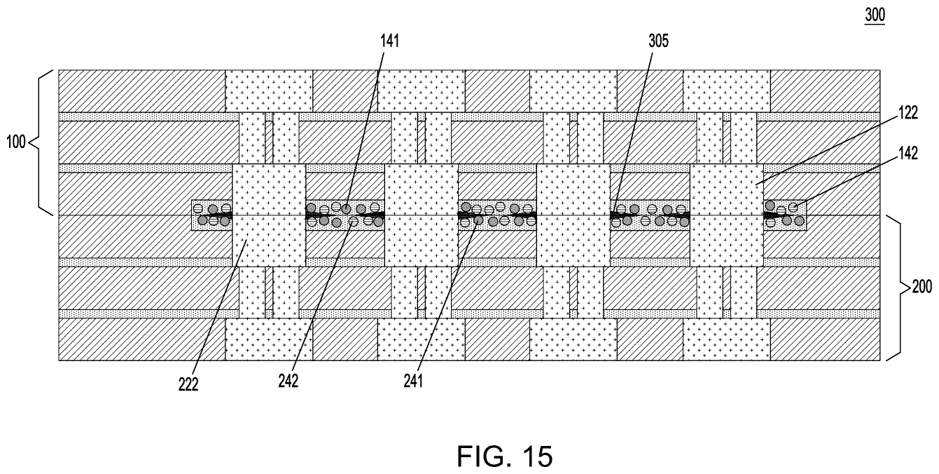

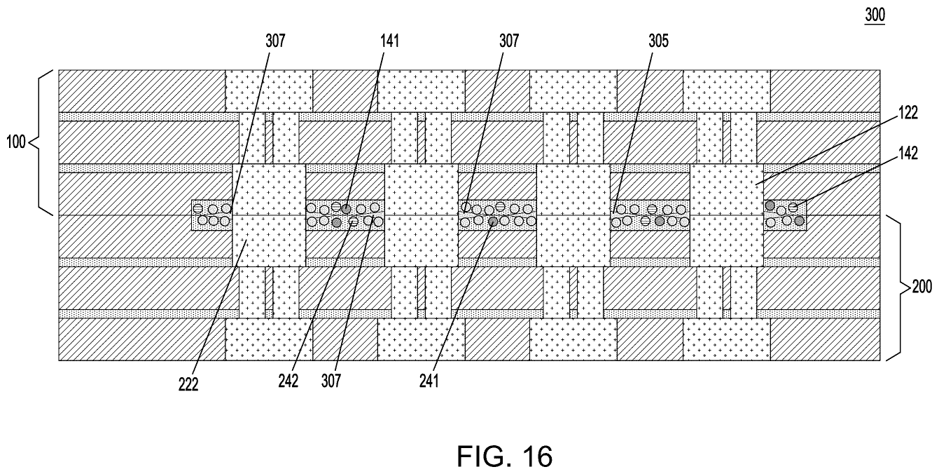

FIG. 15 depicts a cross-sectional view illustrating crack development in the first bonded semiconductor structure 300, and FIG. 16 depicts a cross-sectional view illustrating polymerization of a plurality of healing agents (e.g., first and second healing agents 141 and 241) and filling in of cracks 305 in the first bonded semiconductor structure 300 with polymerized healing agents 307. In connection with FIGS. 15 and 16, the first catalysts 142 and second catalysts 242 are structured to polymerize the first healing agents 141 and second healing agents 241 upon contacting the first healing agents 141 and second healing agents 241. The catalysts 442, 542, 742 and 842 are also structured to polymerize the healing agents 441, 541, 741 and 841, respectively upon contacting the healing agents 441, 541, 741 and 841.

In the case of healing agents that are DCPD, ENB and DCPD/ENB blends, the reaction to create the polymerized healing agents 307 is a ring-opening metathesis polymerization. In the case of healing agents that are mixtures of HOPMDS and PDES, the reaction to create the polymerized healing agents 307 is polycondensation. In the case of epoxy, the reaction to create the polymerized healing agents 307 is also polycondensation, and in the case of a styrene-based system, the reaction to create the polymerized healing agents 307 is radical polymerization. The creation of a crack 305 or cracks 305 adjacent the healing agents (e.g., first and second healing agents 141 and 241) and adjacent the catalysts (e.g., first and second catalysts 142 and 242) causes the healing agents and catalysts to move and contact each other, which breaks, for example, the microcapsules or other structures containing the healing agents and the catalysts. As a result, the healing agents and the catalysts contact and react with each other to polymerize the healing agents. Conditions causing crack (or other void structure) formation can include, but are not necessarily limited to, changes in temperature, humidity, vibrations, electrical fields and/or a combination of such conditions. For example, such conditions may create stresses/strains (e.g., tensile stresses/strains, for example, caused by thermal expansion, compressive stresses/strains caused by, for example, thermal compression) on previously heat treated metal structures created by the opposing pairs of interface contacts (e.g., first and second interface contacts 122 and 222). In other words, the tensile stresses/strains may cause the opposing pairs of interface contacts to expand and/or pull apart from each other and compressive stresses/strains may cause the opposing pairs of interface contacts to compress and/or push against each other causing cracks or other void structures to be formed. Cracks or other void structures may be formed as a result of delamination at dielectric interfaces adjacent the opposing pairs of interface contacts and/or at interfaces between opposing interface contacts. In some cases, cracks or other void structures can grow as temperature increases due to increase in tensile stresses.

In general, cracks or void structures nucleate and grow in high stress/strain regions about and around the hybrid bonded pads (e.g., the hybrid bonded opposing interface contacts of bonded semiconductor structures). As a result of crack or void structure formation, the healing agents and catalysts move and contact each other, which breaks, for example, the microcapsules or other structures containing the healing agents and the catalysts. When the healing agents mix and interact with the catalysts and are polymerized, the polymerized healing agents solidify and restore the structural integrity of the interfaces by filling in the voids created by the cracks or other void structures. As can be seen in FIG. 16, upon propagation of a crack 305 (or other type pf void) adjacent the polymerized plurality of healing agents 307, the polymerized plurality of healing agents 307 are structured to fill in and seal the crack 305 and prevent further propagation of the crack 305. Absent contact with a corresponding catalyst, a healing agent remains dormant.

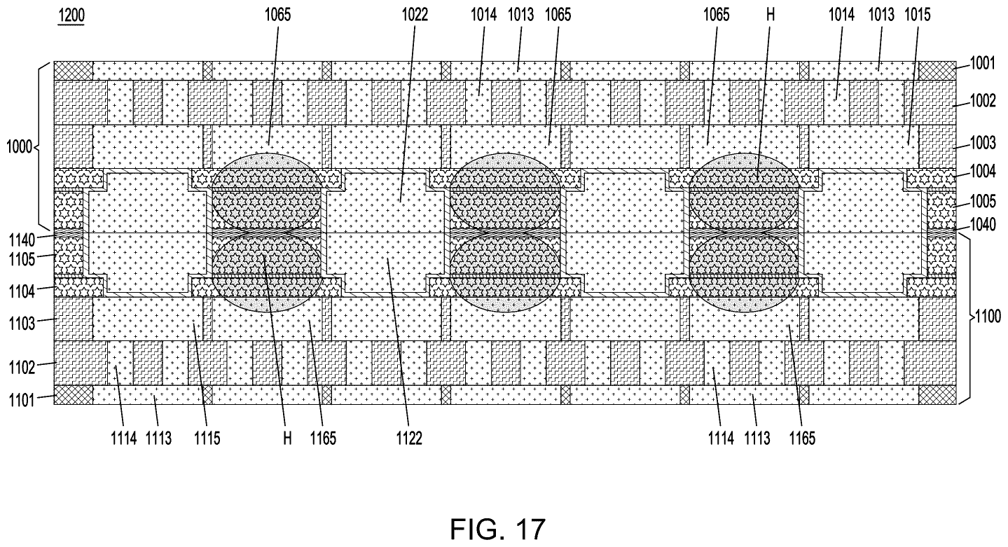

FIG. 17 depicts a cross-sectional view of a fourth bonded semiconductor structure 1200 with alternative repair structures 1040 and 1140. Similar to what is shown in FIG. 7, FIG. 17 depicts a cross-sectional view of a fourth bonded semiconductor structure 1200 with an alternative first semiconductor structure 1000 hybrid bonded to an alternative second semiconductor structure 1100. In more detail, the alternative first semiconductor structure 1000 has been flipped and is positioned on top of the alternative second semiconductor structure 1100. With similar reference numerals representing the same or similar elements, the alternative first semiconductor structure 1000 includes a first dielectric layer stack including dielectric layers 1001, 1002, 1003, 1004 and 1005 and the alternative second semiconductor structure 1100 includes a second dielectric layer stack including dielectric layers 1101, 1102, 1103, 1104 and 1105. The dielectric layers 1001/1101, 1002/1102, 1003/1103, 1004/1104 and 1005/1105 include, but are not necessarily limited to, the same or similar materials as those of the dielectric layers 101/201, 102/202 and 103/203 and/or dielectric layers 111/211 and 112/212. The alternative first semiconductor structure 1000 includes a plurality of first interface contacts 1022 and the alternative second semiconductor structure 1100 includes a plurality of second interface contacts 1122. The plurality of first interface contacts 1022 and the plurality of second interface contacts 1122 are respectively connected to first middle contacts 1015 and second middle contacts 1115. The first middle contacts 1015 are connected to a first subset of first outer contacts 1013 through respective pairs of first vias 1014. The second middle contacts 1115 are connected to a second subset of second outer contacts 1113 through respective pairs of second vias 1114.

A first alternative repair structure 1040 and a second alternative repair structure 1140 each comprise a self-healing polymer. When cracks or void structures are formed by stresses/strains as described hereinabove, the self-healing polymers of the first and second alternative repair structures 1040 and 1140 are activated to fill in the cracks or void structures by application of heat H from first resistive heat elements 1065 and second resistive heat elements 1165. The first resistive heat elements 1065 are connected to a second subset of first outer contacts 1013 through respective pairs of first vias 1014. The second resistive heat elements 1165 are connected to a second subset of second outer contacts 1113 through respective pairs of second vias 1114. The first alternative repair structure 1040 and the second alternative repair structure 1140 respectively on the top surface of the alternative first semiconductor structure 1000 and alternative second semiconductor structure 1100 each comprise a self-healing polymer comprising, for example, a thermoplastic (e.g., polycaprolactone PCL and polyethylene (PE), Diels-alder polymer (e.g., polymers with furan and maleimide groups)), reversible covalent bonding polymers (e.g., polysulfide-based polymer), supramolecular polymers (e.g., polymers with ureidopyrimidinone groups) and polymer blends that exhibit phase separation (e.g., poly (methyl methacrylate) (PMMA) and poly (butyl acrylate) (PBA)). In illustrative embodiments, these materials can break down (e.g., melt, soften, flow, reversible bonding) from their initial form as a film under the application of heat and then fill the cracks or other void structures that formed. Then, the self-healing polymers of the first alternative repair structure 1040 and the second alternative repair structure 1140 reset or return to their initial state or form. Advantageously, the self-healing polymers of the first alternative repair structure 1040 and the second alternative repair structure 1140 fill in the cracks or other void structures, thereby preventing the cracks or other void structures from further growth and propagation.

In illustrative embodiments, the first resistive heat elements 1065 and second resistive heat elements 1165 comprise copper metal structures. The temperature ranges needed to activate the self-healing polymers varies depending on the specific type of polymer and/or the mechanism that it leverages to self-heal. A temperature range for activation for the listed materials is about 40° C. to about 120° C. To achieve these temperatures, the first resistive heat elements 1065 and second resistive heat elements 1165 are designed accordingly and appropriate voltages per their design and size are applied to the first resistive heat elements 1065 and second resistive heat elements 1165 through the second subset of first outer contacts 1013 and the second subset of second outer contacts 1113.

The first interface contacts 1022, the first middle contacts 1015, the first outer contacts 1013, the second interface contacts 1122, the second middle contacts 1115 and the second outer contacts 1113 can be for example, pads or other interconnects. In illustrative embodiments, the first interface contacts 1022, the first middle contacts 1015, the first outer contacts 1013, the second interface contacts 1122, the second middle contacts 1115, the second outer contacts 1113, the first vias 1014 and the second vias 1114 include the same or similar materials as the first outer contacts 121, the first interface contacts 122, the second outer contacts 221, the second interface contacts 222, the first vias 123 and the second vias 223, and can be deposited using, for example, deposition techniques such as CVD, PECVD, RFCVD, PVD, ALD, MBD, PLD, LSMCD, sputtering and/or plating, followed by a planarization process such as, CMP to remove excess portions of the metal material from on top of dielectric layers.

It is to be appreciated that the techniques as disclosed herein enable construction of hybrid bonded structures which provide various advantages over conventional packaging structures and techniques as discussed above. For example, the structure advantageously uses corresponding and matching metal (e.g., Cu) interface contacts (e.g., pads) on each respective semiconductor build's top joining surface. The matching interface contacts are disposed within a dielectric surface (e.g., TEOS, SiCN, etc.). Self-healing agents are integrated into the top dielectric surface and about and around the matching interface contacts. The healing agents can be microcapsules, coatings and/or in channels. The materials of which the self-healing agents are formed may be, for example, polymer-based materials or other chemical-based materials. The self-healing agents are initially dormant unless activated by contact with a catalyst. When cracks and/or other void structures form, the cracks or other void structures cause the healing agents and catalysts to collide, thereby resulting in a chemical reaction to polymerize the healing agents. The polymerized healing agents then fill the cracks and/or other void structures. The illustrative embodiments advantageously increase reliability, durability, longevity and robustness of hybrid bonded semiconductor package assemblies by filling in the cracks and/or other void structures with the polymerized healing agents, thereby preventing further crack propagation. As a result, the structural integrity of the package assemblies is improved.

Although exemplary embodiments have been described herein with reference to the accompanying figures, it is to be understood that the disclosure is not limited to those precise embodiments, and that various other changes and modifications may be made therein by one skilled in the art without departing from the scope of the appended claims.

What is claimed is:

1. A semiconductor device, comprising:
a first semiconductor structure bonded to a second semiconductor structure;
a plurality of metal pads at an interface portion between the first semiconductor structure and the second semiconductor structure; and
a structure disposed around the plurality of metal pads, wherein the structure comprises a plurality of chemical agents.

2. The semiconductor device of claim 1, wherein the plurality of chemical agents comprise a plurality of healing agents in a resin matrix.

3. The semiconductor device of claim 2, wherein the resin matrix includes a plurality of catalysts, and wherein the plurality of catalysts are structured to polymerize the plurality of healing agents upon contacting the plurality of healing agents.

4. The semiconductor device of claim 3, wherein one or more of the plurality of catalysts comprise a Grubbs catalyst.

5. The semiconductor device of claim 3, wherein upon propagation of a crack adjacent the polymerized plurality of healing agents, the polymerized plurality of healing agents are structured to seal the crack and prevent further propagation of the crack.

6. The semiconductor device of claim 2, wherein the plurality of healing agents are in respective ones of a plurality of capsules.

7. The semiconductor device of claim 2, wherein the plurality of healing agents are in a plurality of channels.

8. The semiconductor device of claim 1, wherein the first semiconductor structure is hybrid bonded to the second semiconductor structure.

9. The semiconductor device of claim 1, wherein the plurality of metal pads are disposed in a dielectric layer.

10. The semiconductor device of claim 1, wherein the structure comprises a plurality of respective portions spaced apart from each other and corresponding to respective ones of the plurality of metal pads.

11. The semiconductor device of claim 1, further comprising at least one dielectric layer disposed around the plurality of metal pads, wherein the structure is disposed over and under the at least one dielectric layer.

12. A semiconductor device, comprising:
a first semiconductor structure comprising a first plurality of metal pads;
a second semiconductor structure comprising a second plurality of metal pads;
wherein the first semiconductor structure is bonded to the second semiconductor structure;
wherein respective ones of the first plurality of metal pads are aligned with respective ones of the second plurality of metal pads; and
a repair structure disposed around the respective ones of the first plurality of metal pads and the second plurality of metal pads.

13. The semiconductor device of claim 12, wherein the repair structure comprises a plurality of healing agents.

14. The semiconductor device of claim 13, wherein the plurality of healing agents are in respective ones of a plurality of capsules.

15. The semiconductor device of claim 13, wherein the plurality of healing agents are in a plurality of channels.

16. The semiconductor device of claim 13, wherein the repair structure further comprises a plurality of catalysts, and wherein the plurality of catalysts are structured to polymerize the plurality of healing agents upon contacting the plurality of healing agents.

17. The semiconductor device of claim 12, wherein the first semiconductor structure is hybrid bonded to the second semiconductor structure.

18. A semiconductor device, comprising:
two or more semiconductor dies hybrid bonded together;
a plurality of metal structures at an interface portion between a first semiconductor die of the two or more semiconductor dies and a second semiconductor die of the two or more semiconductor dies; and
a structure disposed around respective ones of the plurality of metal structures, wherein the structure comprises a plurality of chemical agents.

19. The semiconductor device of claim 18, wherein:
the plurality of chemical agents comprise a plurality of healing agents in a resin matrix;
the resin matrix includes a plurality of catalysts; and
the plurality of catalysts are structured to polymerize the plurality of healing agents upon contacting the plurality of healing agents.

20. The semiconductor device of claim 19, wherein upon propagation of a crack adjacent the polymerized plurality of healing agents, the polymerized plurality of healing agents are structured to seal the crack and prevent further propagation of the crack.
